(19) United States
(12) Patent Application Publication
(10) Pub. No.: US 2014/0054618 A1
(43) Pub. Date: Feb. 27, 2014

(54) LIGHT-EMITTING DIODE DEVICES

(71) Applicant: SYUE- MIN LI, Taipei (TW)

(72) Inventor: SYUE- MIN LI, Taipei (TW)

(21) Appl. No.: 13/737,085

(22) Filed: Jan. 9, 2013

(30) Foreign Application Priority Data
Aug. 22, 2012 (TW) 101130560

(51) Int. Cl. H01L 33/08; H01L 33/60

(52) U.S. Cl. CPC H01L 33/08; H01L 33/60
USPC 257/88; 257/98; 438/29

(57) ABSTRACT

An LED device includes an LED chip having a sapphire substrate, a first-type semiconductor layer on the substrate, a second-type semiconductor layer disposed on the first-type semiconductor layer, a first via hole passing through the sapphire substrate and the first-type semiconductor layer, a second via hole passing through the sapphire substrate, and an insulation layer coated on an inner wall of the first via hole; a transparent conductive layer made of electrically conductive material and formed on the second-type semiconductor layer; a cover layer formed on the transparent conductive layer; electrical conductors, each disposed within one of the via holes, wherein the electrical conductor in the first via hole is electrically connected to the second-type semiconductor layer and the electrical conductor in the second via hole is electrically connected to the first-type semiconductor layer; and two linkers for connection to external circuitry, formed on a surface of the sapphire.

### PRIORITY CLAIM

This application claims priority to R.O.C. Patent Application No. 101130560 filed Aug. 22, 2012, the entirety of which is incorporated herein by reference.

### BACKGROUND OF THE INVENTION

1. Field of the Invention

The present invention relates to light-emitting diode (LED) devices.

2. Description of the Prior Art

In the technical field of illumination applications, light-emitting diode (LED) products have gained more and more interest due to the advantages of saving energy and reducing carbon dioxide emissions. However, the conventional LED architectures are known to suffer from the problem of low light emission efficiency resulting from the blocking of radiative lights by P- and N-type electrodes.

The invention overcomes the conventional drawbacks by providing new white-light LED devices which differ from those developed by Nichia Corporation in terms of structural arrangement.

### SUMMARY OF THE INVENTION

According to an aspect of the invention, a light-emitting diode device is provided, which comprises: a light-emitting diode (LED) chip comprising a sapphire substrate, a first-type semiconductor layer disposed on the substrate, a second-type semiconductor layer disposed on the first-type semiconductor layer, a first via hole passing through the sapphire substrate and the first-type semiconductor layer, a second via hole passing through the sapphire substrate, and an insulation layer coated on an inner wall of the first via hole; a transparent conductive layer made of electrically conductive material and formed on the second-type semiconductor layer; a cover layer formed on the transparent conductive layer; electrical conductors, each disposed within one of the via holes, wherein the electrical conductor in the first via hole is electrically connected to the second-type semiconductor layer and the electrical conductor in the second via hole is electrically connected to the first-type semiconductor layer; and two linkers adapted for connection to external circuitry, formed on a surface of the sapphire substrate opposite to the surface on which the first-type and second-type semiconductor layers are disposed.

### BRIEF DESCRIPTION OF THE DRAWINGS

The above and other objects, features and effects of the invention will become apparent with reference to the following description of the preferred embodiments taken in conjunction with the accompanying drawings, in which:

FIG. 1 is a schematic cross-sectional view of the LED device according to the first preferred embodiment of the invention;

FIG. 2 is a schematic diagram illustrating the light tunnel created by the laminated transparent light guide layer according to the first preferred embodiment of the invention;

FIG. 3 is a schematic cross-sectional view of the LED device according to the second preferred embodiment of the invention;

FIGS. 4-7 are schematic diagrams showing a method for producing the LED device according to the invention;

FIG. 8 is a schematic cross-sectional view of the LED device according to the third preferred embodiment of the invention;

FIG. 9 is a schematic cross-sectional view of the LED device according to the fourth preferred embodiment of the invention;

FIG. 10 is a schematic cross-sectional view of the LED device according to the fifth preferred embodiment of the invention;

FIG. 11 is a schematic cross-sectional view of the LED device according to the sixth preferred embodiment of the invention;

FIG. 12 is a schematic cross-sectional view of the LED device according to the seventh preferred embodiment of the invention;

FIG. 13 is a schematic cross-sectional view of the LED device according to the eighth preferred embodiment of the invention; and

FIG. 14 is a schematic cross-sectional view of the LED device according to the ninth preferred embodiment of the invention.

### DETAILED DESCRIPTION OF THE PREFERRED EMBODIMENTS

Before the present invention is described in greater detail, it should be noted that the same or like elements are denoted by the same reference numerals throughout the disclosure. Moreover, the elements shown in the drawings are not illustrated in actual scale, but are expressly illustrated to explain in an intuitive manner the technical feature of the invention disclosed herein.

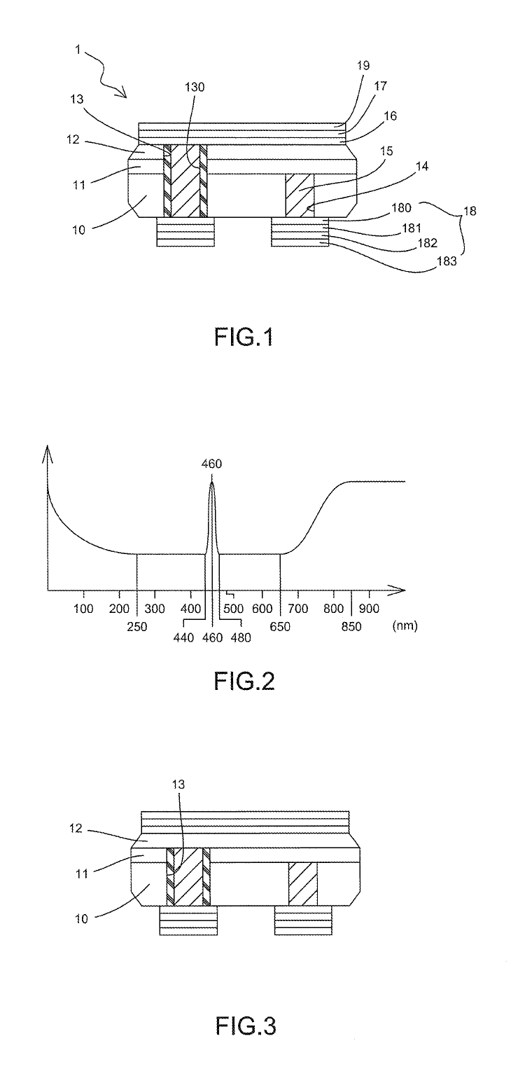

FIG. 1 is a schematic cross-sectional view of the LED device according to the first preferred embodiment of the invention.

Referring to FIG. 1, the LED device according to the first preferred embodiment of the invention comprises an LED chip 1. The LED chip 1 comprises a sapphire substrate 10, a first-type semiconductor layer 11 disposed on the substrate 10, and a second-type semiconductor layer 12 disposed on the first-type semiconductor layer 11. According to this embodiment, the first-type semiconductor layer 11 is an N-type semiconductor layer, whereas the second-type semiconductor layer 12 is a P-type semiconductor layer. The LED chip 1 is subjected to a dry etching process using inductively couplec plasma (ICP) or a laser drilling process, so that it is formed with a first via hole 13 passing through the sapphire substrate 10, the N-type semiconductor layer 11 and the P-type semiconductor layer 12, and a second via hole 14 passing through the sapphire substrate 10. The first via hole 13 has an inner wall, on which an insulation layer 130 made of silicon dioxide, a polyimide material or any other suitable material is disposed.

According to this embodiment, the sapphire substrate 10 used preferably has a thickness from 10 μm to 50 μm. However, the sapphire substrate 10 can optionally have a thickness falling outside of the range described above.

A transparent conductive layer 16 made of conductive indium tin oxide (ITO) is formed on the P-type semiconductor layer 12. A cover layer 17 made of, for example, silicon dioxide (SiO₂) is formed on the transparent conductive layer 16, so as to prevent the transparent conductive layer 16 from oxidation. It should be noted that the transparent conductive layer 16 and the cover layer 17 can be alternatively made of any other material suitable for their intended uses.

Electrical conductors 15 are disposed within the via holes 13, 14, respectively, so that the electrical conductor 15 in the via hole 13 is electrically connected to the transparent conductive layer 16 disposed on the P-type semiconductor layer 12 and the electrical conductor 15 in the via hole 14 is electrically connected to the N-type semiconductor layer 11.

Two linkers 18 adapted for connection to external circuitry are formed on a surface of the sapphire substrate 10 opposite to the surface on which the semiconductor layers 11, 12 are disposed. Each of the linkers 18 is electrically connected to a corresponding one of the electrical conductors 15 and includes a first conductive layer 180 disposed on the sapphire substrate 10 and electrically connected to the electrical conductor 15 corresponding thereto, a reflective conductive layer 181 formed on the first conductive layer 180, a second conductive layer 182 formed on the reflective layer 181, and a third conductive layer 183 formed on the second conductive layer 182.

According to this embodiment, the first conductive layer 180 may be made of ITO; the reflective layer 181 may be made of any electrically conductive material suitable for its intended use; the second conductive layer 182 may be a nickel/gold layer; and the third conductive layer 183 is configured in the form of a bump. However, the linkers 18, as well as the respective conductive layers 180, 181, 182, 183, can be made from different material or fabricated into a different configuration from those described above, so long as the selected material and configuration can surely achieve the intended purpose of electrically connecting the electrical conductors 15 to the external circuitry (not shown).

It is known that the sapphire substrate 10 would tend to crack as its thickness is reduced. In the LED device disclosed herein, however, the overall structural strength can be maintained by installation of the linkers 18, thereby preventing the sapphire substrate 10 from cracking and avoiding the occurrence of open circuit or short circuit. Meanwhile, the heat dissipation efficiency from the LED device will be further enhanced and the possible luminous decay caused by LED overheating is prevented, as the thickness of the sapphire substrate 10 is reduced and the thickness of the linkers 18 is increased.

It should be noted that the LED device disclosed herein can further comprise a laminated transparent light guide layer 19 formed atop the cover layer 17. The laminated transparent light guide layer 19 is adapted to direct light towards a single direction, so that the light emitted the LED device can be concentrated to increase the brightness. The light tunnel created by the laminated transparent light guide layer 19 is illustrated in FIG. 2.

The laminated transparent light guide layer 19 includes a plurality of sub-layers having refractive indexes of 2.2˜2.3/2.3˜2.4/2.2˜2.3/2.3˜2.4, respectively. The overall refractive index of the laminated transparent light guide layer 19 is close to the refractive indexes 2.4˜2.5 of gallium nitride (GaN) or gallium arsenide (GaAs) and is therefore suitable for directing the emitted blue light towards a single direction and avoiding multiple reflection of light.

In addition, the semiconductor layers 11, 12, as well as the surface of the sapphire substrate 10 opposite to the surface on which the semiconductor layers 11, 12 are disposed, have edges configured into diamond light-guide edges, thereby increasing light emission by more than 20%. The LED device disclosed herein is not shielded by any metallic material around 360 degree, so that more than 90% of the light emitted from the semiconductor layers 11, 12 can be effectively directed outward from the LED device.

In the first preferred embodiment described above, the linkers 18 are formed on the surface of the sapphire substrate 10 opposite to the surface on which the semiconductor layers 11, 12 are disposed, while the transparent conductive layer 16, the cover layer 17 and the laminated transparent light guide layer 19 are sequentially formed on the P-type semiconductor layer 12. However, the linkers 18 can be swapped in position with the transparent conductive layer 16, the cover layer 17 and the laminated transparent light guide layer 19.

It should be noted that some or all of the technical features disclosed in the first preferred embodiment are also applicable to the embodiments described below.

FIG. 3 is a schematic view of the LED device according to the second preferred embodiment of the invention.

The LED device according to the second preferred embodiment differs from that disclosed in the first preferred embodiment in that the first via hole 13 is fabricated to only pass through the sapphire substrate 10 and the first semiconductor layer 11, so that the electrical conductor 15 in the via hole 13 is electrically connected to the P-type semiconductor layer 12.

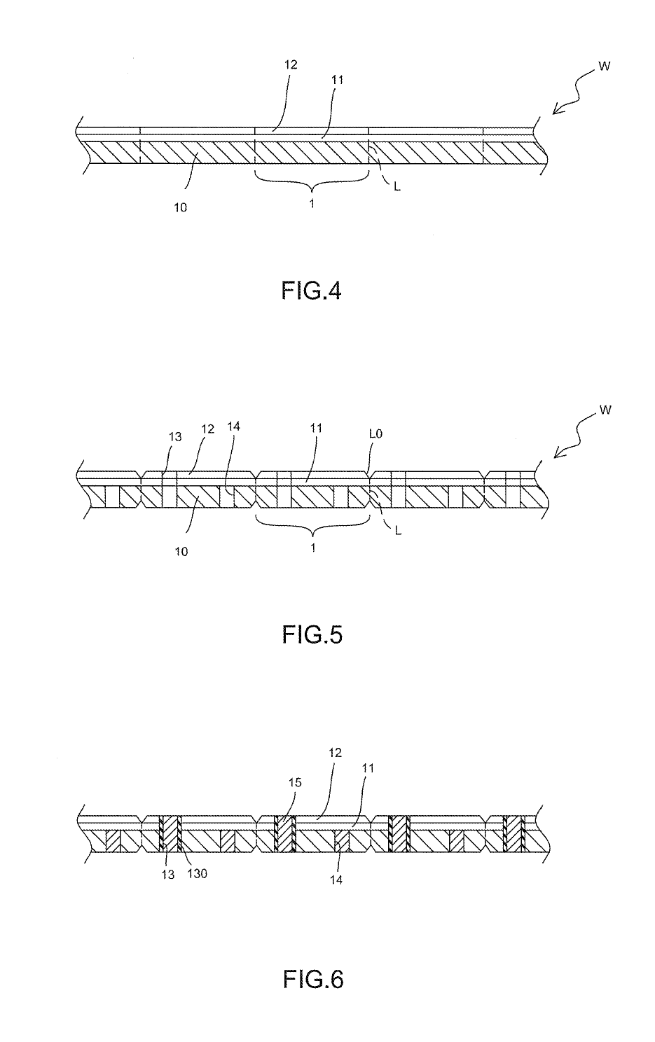

FIGS. 4-7 are schematic diagrams showing a method for producing the LED device according to the invention.

As shown in FIG. 4, the method starts with providing an LED wafer W (only a part of the LED wafer W is shown). The wafer W comprises a plurality of LED chips 1, each being separate from an adjacent LED chip by a dicing line L. Each of the LED chips 1 comprises a sapphire substrate 10, an N-type semiconductor layer 11 disposed on the substrate 10, and a P-type semiconductor layer 12 disposed on the N-type semiconductor layer 11, as described above.

Next, as shown in FIG. 5, each of the LED chips 1 is subjected to a dry etching process using inductively coupled plasma (ICP) or a laser drilling process, so that it is formed with a first via hole 13 passing through either the sapphire substrate 10, the N-type semiconductor layer 11 and the P-type semiconductor layer 12 (in the case of the first preferred embodiment), or the sapphire substrate 10 and the N-type semiconductor layer 11 (in the case of the second preferred embodiment), and a second via hole 14 only penetrating through the sapphire substrate 10. During the fabrication of the via holes 13, 14, generally V-shaped notches L0 are generated at the same time along the respective dicing lines L across both surfaces of the wafer W. When the wafer W is diced into individual LED chips 1, the notches L0 make the edges of the LED chips 1 become diamond light-guide edges, thereby increasing light emission by more than 20%. Each one of the resultant LED chips 1 is not shielded by any metallic material around 360 degree, so that more than 90% of the light emitted from the semiconductor layers 11, 12 can be effectively directed outward from the respective LED chips 1. This is a key factor for the LED device to attain a lighting efficiency of greater than 160 lm/W.

Afterwards, the first via hole 13 is coated on its inner wall with an insulation layer 130, as shown in FIG. 6. The insulation layer 130 may be made of silicon dioxide or a polyimide material.

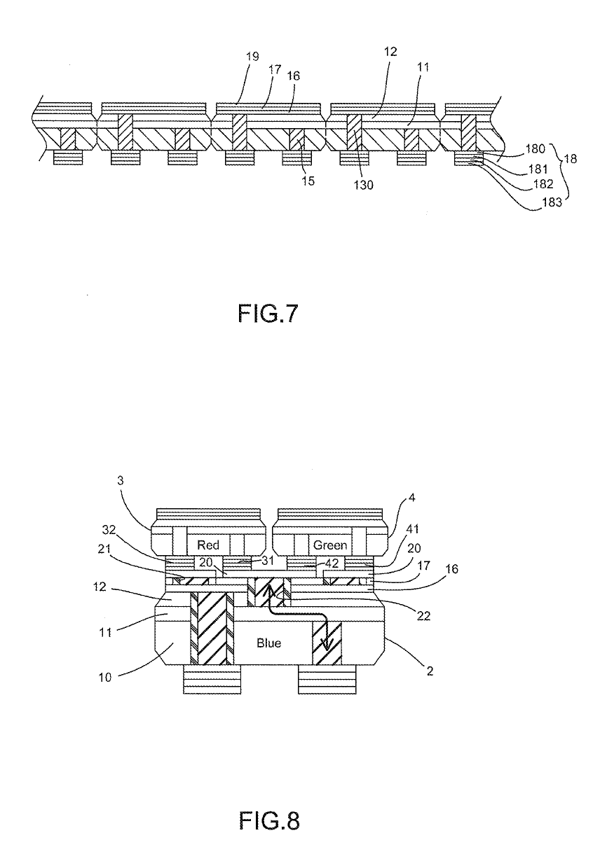

After the formation of the insulation layer 130, respective electrical conductors 15 are formed within the via holes 13, 14, so that the electrical conductor 15 in the via hole 13 is electrically connected to the transparent conductive layer 16 disposed on the P-type semiconductor layer 12 and the electrical conductor 15 in the via hole 14 is electrically connected to the N-type semiconductor layer 11 (see FIG. 7).

Referring to FIG. 7, a transparent conductive layer 16 made of indium tin oxide (ITO) is formed on the P-type semiconductor layer 12. A cover layer 17 is formed on the transparent conductive layer 16, so as to prevent the transparent conductive layer 16 from oxidation. A laminated light guide layer 19 is then formed atop the cover layer 17.

Meanwhile, a plurality of linkers 18 adapted for connection to external circuitry are formed with respect to the electrical conductors 15 on a surface of the sapphire substrate 10 opposite to the surface on which the semiconductor layers 11, 12 are disposed. Each of the linkers 18 is electrically connected to a corresponding one of the electrical conductors 15 and includes a first conductive layer 180 disposed on the sapphire substrate 10 and electrically connected to the electrical conductor 15 corresponding thereto, a reflective layer 181 formed on the first conductive layer 180, a second conductive layer 182 formed on the reflective layer 181, and a third conductive layer 183 formed on the second conductive layer 182.

Finally, the wafer W is diced along the dicing lines L into a plurality of LED devices shown in FIG. 1.

It should be noted that the linkers 18 may be made from ITO to achieve a 360 degree all-around illumination.

Meanwhile, the electrical conductors 15 may also be made from ITO, so as to avoid using the metallic material that would block or reduce light emission.

FIG. 8 is a schematic view of the LED device according to the third preferred embodiment of the invention.

As shown in FIG. 8, the LED device according to this embodiment comprises a first LED chip 2, a second LED chip 3 and a third LED chip 4, each adapted to emit a different color of light. In this embodiment, the first LED chip 2 emits blue light upon being energized, whereas the second LED chip 3 and the third LED chip 4 emit red light and green light, respectively.

The first LED chip 2 has a configuration generally identical to the LED chip 1 disclosed in the first preferred embodiment. It merely differs from the LED chip 1 in the replacement of the laminated light guide layer 19 shown in FIG. 1 with three conductive islands 30 electrically insulated from one another, and the formation of a communication hole 21 that connects the conductive layer 16 to a corresponding one of the conductive islands 20 and a through hole 22 that connects the N-type semiconductor layer 11 to a corresponding one of the conductive islands 20. The communication hole 21 and the through hole 22 are coated on their inner walls with an insulation layer 210, 220. The communication hole 21 and the through hole 22 are filled with conductive material 23, so that one of the three conductive island 20 is electrically connected to the conductive layer 16 and another one of the three conductive island 20 is electrically connected to the N-type semiconductor layer 11 of the first LED chip 2.

The second LED chip 3 may have a configuration generally identical to the LED chip 1 disclosed in the first preferred embodiment. Alternatively, the second LED chip 3 may be a conventional LED chip. The second LED chip 3 is flip-chip mounted on the cover layer 17, so that the P-type semiconductor layer 32 of the second LED chip 3 is electrically connected to the conductive island 20 to which the conductive layer 16 is electrically connected, and that the N-type semiconductor layer 31 of the second LED chip 3 is electrically connected to the conductive island 20 which is not electrically connected to either the conductive layer 16 or the N-type semiconductor layer 11 of the first LED chip 2.

The third LED chip 4 may have a configuration generally identical to the LED chip 1 disclosed in the first preferred embodiment. Alternatively, the third LED chip 4 may be a conventional LED chip. The third LED chip 4 is also flip-chip mounted on the cover layer 17, so that the P-type semiconductor layer 32 of the third LED chip 4 is electrically connected to the conductive island 20 to which the N-type semiconductor layer 31 of the second LED chip 3 is electrically connected, and that the N-type semiconductor layer 41 of the third LED chip 4 is electrically connected to the conductive island 20 to which the N-type semiconductor layer 11 of the first LED chip 2 is electrically connected.

By virtue of the structural arrangement described above, the LED device is capable of emitting white light in the absence of any phosphor powder.

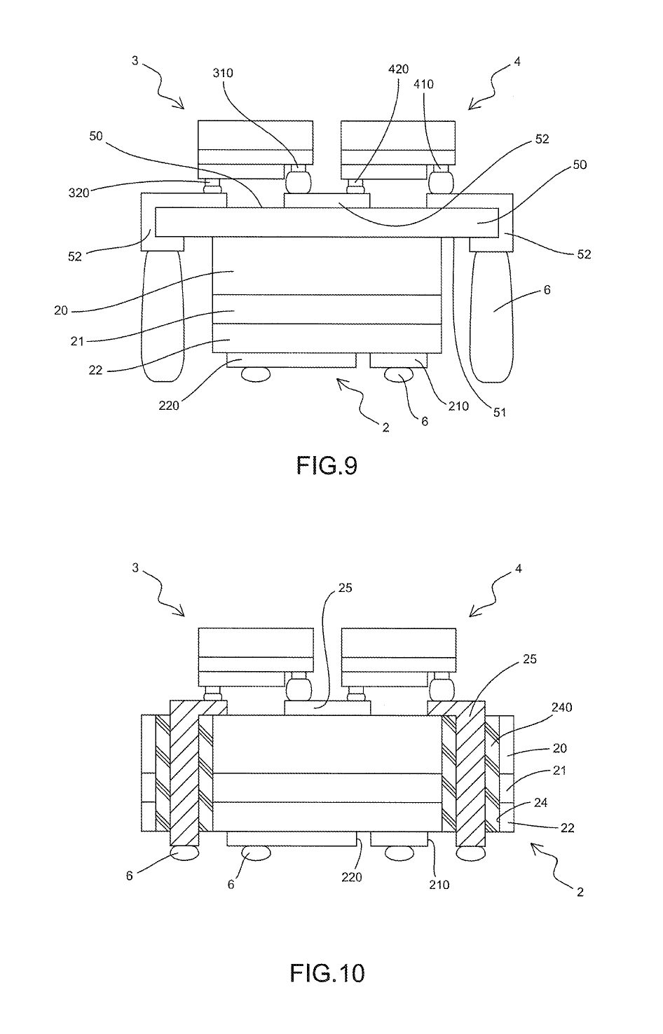

FIG. 9 is a schematic view of the LED device according to the fourth preferred embodiment of the invention.

As shown in FIG. 9, the LED device according to this embodiment comprises a first LED chip 2, a second LED chip 3, a third LED chip 4, and a substrate 5.

In this embodiment, the substrate 5 is a glass substrate having a first mounting surface 50 and a second mounting surface 51 opposite to the first mounting surface 50. A plurality of conductive traces 52, preferably made of ITO, are formed on the first mounting surface 50. In this embodiment, some of the conductive traces 52 extend from the first mounting surface 50 to the second mounting surface 51.

The first LED chip 2 is mounted on the substrate 5 and comprises a sapphire substrate 20 disposed on the first mounting surface 50 of the substrate 5, an N-type semiconductor layer 21 mounted on the sapphire substrate 20, a P-type semiconductor layer 22 mounted on the N-type semiconductor layer 21, and N-type and P-type electrodes 210, 220 adapted for electrical connection to external circuitry (not shown). The N-type and P-type electrodes 210, 220 are electrically connected to the N-type semiconductor layer 21 and the P-type semiconductor layer 22, respectively.

The second LED chip 3 has a configuration identical to the first LED chip 2 and is flip-chip mounted on the first mounting surface 50 of the substrate 5, so that the P-type electrode 320 of the second LED chip 3 is electrically connected to one of the conductive traces 52 extending from the first mounting surface 50 to the second mounting surface 51, and that the N-type electrode 310 of the second LED chip 3 is electrically connected to a conductive trace 52 which does not extend to the second mounting surface 51.

The third LED chip 4 has a configuration identical to the first LED chip 2 and is flip-chip mounted on the first mounting surface 50 of the substrate 5, so that the P-type electrode 420 of the third LED chip 4 is electrically connected to the conductive trace 52 to which the N-type electrode 310 of the second LED chip 3 is electrically connected, and that the N-type electrode 410 of the third LED chip 4 is electrically connected to another one of the conductive traces 52 extending from the first mounting surface 50 to the second mounting surface 51.

The N-type and P-type electrodes 210, 220 of the first LED chip 2, as well as the extension portions of the conductive traces 52 which extend on the second mounting surface 51, are formed with a conductive pad 6, respectively, for electrical connection to external circuitry (not shown).

FIG. 10 is a schematic view of the LED device according to the fifth preferred embodiment of the invention.

As shown in FIG. 10, the LED device according to this embodiment comprises a first LED chip 2, a second LED chip 3, and a third LED chip 4.

The first LED chip 2 comprises a sapphire substrate 20, an N-type semiconductor layer 21 disposed on the sapphire substrate 20, a P-type semiconductor layer 22 disposed on the N-type semiconductor layer 21, and N-type and P-type electrodes 210, 220 electrically connected to the N-type semiconductor layer 21 and the P-type semiconductor layer 22, respectively, and adapted for electrical connection to external circuitry (not shown).

In this embodiment, the first LED chip 2 is formed with two through holes 24 passing through the substrate 20 and the semiconductor layers 21, 22. The through holes 24 are coated on their inner walls with an insulation layer 240. A plurality of conductive traces 25, preferably made of ITO, are formed on a surface of the substrate 20 opposite to the surface on which the semiconductor layers 11, 12 are disposed. In this embodiment, some of the conductive traces 25 extend through the through holes 24 and protrude out from the first LED chip 2.

The second LED chip 3 has a configuration identical to the first LED chip 2 and is flip-chip mounted on the surface of the substrate 20 of the first LED chip 2 on which the conductive traces 25 are mounted, so that the P-type electrode 320 of the second LED chip 3 is electrically connected to one of the conductive traces 25 extending through the through holes 24, and that the N-type electrode 310 of the second LED chip 3 is electrically connected to a conductive trace 25 which does not extend into anyone of the through holes 24.

The third LED chip 4 has a configuration identical to the first LED chip 2 and is flip-chip mounted on the surface of the substrate 20 of the first LED chip 2 on which the conductive traces 25 are mounted, so that the P-type electrode 420 of the third LED chip 4 is electrically connected to the conductive traces 25 to which the N-type electrode 310 of the second LED chip 3 is electrically connected, and that the N-type electrode 410 of the third LED chip 4 is electrically connected to the other one of the conductive traces 25 extending through the through holes 24.

The N-type and P-type electrodes 210, 220 of the first LED chip 2, as well as the protruded portions of the conductive traces 25 which extend through the through holes 24 and protrude out from the first LED chip 2, are formed with a conductive pad 6, respectively, for electrical connection to external circuitry (not shown).

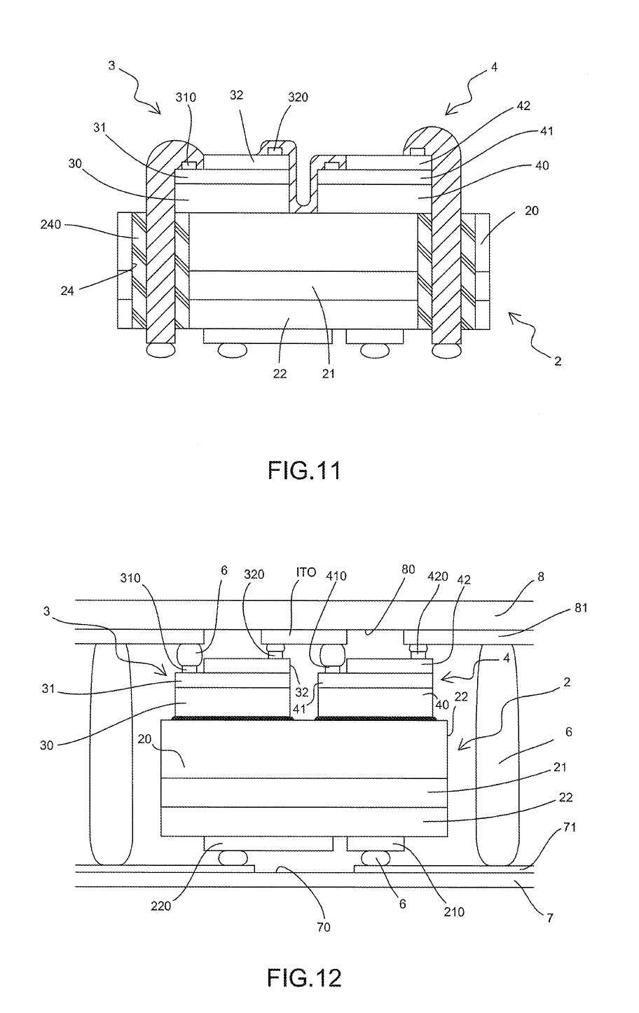

FIG. 11 is a schematic view of the LED device according to the sixth preferred embodiment of the invention.

As shown in FIG. 11, the LED device according to this embodiment comprises a first LED chip 2, a second LED chip 3, a third LED chip 4 and a plurality of conductors 25.

The first LED chip 2 comprises a sapphire substrate 20, an N-type semiconductor layer 21 mounted on the sapphire substrate 20, a P-type semiconductor layer 22 mounted on the N-type semiconductor layer 21, N-type and P-type electrodes 210, 220 adapted for electrical connection to external circuitry (not shown), and two through holes 24 passing through the sapphire substrate 20, the N-type semiconductor layer 21 and the P-type semiconductor layer 22. The through holes 24 are coated on their inner walls with an insulation layer 240.

The second LED chip 3 comprises a sapphire substrate 30 disposed on a surface of the sapphire substrate 20 of the first LED chip 2 opposite to the surface on which the N-type semiconductor layer 21 of the first LED chip 2 is disposed, an N-type semiconductor layer 31 disposed on the sapphire substrate 30, and a P-type semiconductor layer 32 disposed on the N-type semiconductor layer 31. The N-type semiconductor layer 31 and the P-type semiconductor layer 32 are formed with an N-type electrode 310 and a P-type electrode 320, respectively.

The third LED chip 4 is mounted alongside the second LED chip 3 on the surface of the sapphire substrate 20 of the first LED chip 2 opposite to the surface on which the N-type semiconductor layer 21 of the first LED chip 2 is disposed. The third LED chip 4 comprises a sapphire substrate 40 disposed on the sapphire substrate 20 of the first LED chip 2, an N-type semiconductor layer 41 disposed on the sapphire substrate 40, and a P-type semiconductor layer 42 disposed on the N-type semiconductor layer 41. The N-type semiconductor layer 41 and the P-type semiconductor layer 42 are formed with an N-type electrode 410 and a P-type electrode 420, respectively.

One of the conductors 25 extends from the N-type electrode 310 of the second LED chip 3 through one of the through holes 24 and further protrudes out from the first LED chip 2. Another one of the conductors 25 extends from the P-type electrode 420 of the third LED chip 4 through the other one of the through holes 24 and further protrudes out from the first LED chip 2.

A still another one of the conductors 25 extends from the P-type electrode 320 of the second LED chip 3 to the N-type electrode 410 of the third LED chip 4.

The N-type and P-type electrodes 210, 220 of the first LED chip 2, as well as the protruded portions of the conductors 25 which extend through the through holes 24 and protrude out from the first LED chip 2, are formed with a conductive pad 6, respectively, for electrical connection to external circuitry (not shown).

FIG. 12 is a schematic view of the LED device according to the seventh preferred embodiment of the invention.

As shown in FIG. 12, the LED device according to this embodiment comprises a first LED chip 2, a second LED chip 3, a third LED chip 4, a first mounting substrate 7 and a second mounting substrate 8.

The first mounting substrate 7 includes a first surface 70 and a plurality of predetermined circuit traces 71 overlaid on the first surface 70.

The first LED chip 2 comprises a sapphire substrate 20, an N-type semiconductor layer 21 disposed on the sapphire substrate 20, a P-type semiconductor layer 22 disposed on the N-type semiconductor layer 21, and N-type and P-type electrodes 210, 220 adapted for electrical connection to external circuitry (not shown). The electrodes 210, 220 are formed with a conductive pad 6, respectively. The first LED chip 2 is flip-chip mounted on the first mounting substrate 7 by electrically connecting the conductive pads 6 to the corresponding circuit traces 71 overlaid on the first mounting substrate 7.

The second LED chip 3 may have a configuration identical to or different from the first LED chip 2. In this embodiment, the second LED chip 3 comprises a sapphire substrate 30 disposed on a surface of the sapphire substrate 20 of the first LED chip 2 opposite to the surface on which the N-type semiconductor layer 21 of the first LED chip 2 is disposed, an N-type semiconductor layer 31 disposed on the sapphire substrate 30, and a P-type semiconductor layer 32 disposed on the N-type semiconductor layer 31. The N-type semiconductor layer 31 and the P-type semiconductor layer 32 are formed with an N-type electrode 310 and a P-type electrode 320, respectively.

The third LED chip 4 may have a configuration identical to or different from the first and second LED chips 2, 3. In this embodiment, the third LED chip 4 is mounted alongside the second LED chip 3 on the surface of the sapphire substrate 20 of the first LED chip 2 opposite to the surface on which the N-type semiconductor layer 21 of the first LED chip 2 is disposed. The third LED chip 4 comprises a sapphire substrate 40 disposed on the substrate 20 of the first LED chip 2, an N-type semiconductor layer 41 disposed on the sapphire substrate 40, and a P-type semiconductor layer 42 disposed on the N-type semiconductor layer 41. The N-type semiconductor layer 41 and the P-type semiconductor layer 42 are formed with an N-type electrode 410 and a P-type electrode 420, respectively.

The second mounting substrate 8 includes a first surface 80 and a plurality of predetermined circuit traces 81 overlaid on the first surface 80. The first surface 80 of the second mounting substrate 8 is oppositely mounted with respect to the first surface 70 of the first mounting substrate 7, so that the N-type electrode 310 of the second LED chip 3 is electrically connected to one of the predetermined circuit traces 81 of the second mounting substrate 8 via a conductive pad 6, the P-type electrode 320 of the second LED chip 3 and the N-type electrode 410 of the third LED chip 4 is electrically connected to one of the predetermined circuit traces 81 of the second mounting substrate 8 via conductive pads 6, respectively, and the P-type electrode 420 of the third LED chip 4 is electrically connected to one of the predetermined circuit traces 81 of the second mounting substrate 8 via a conductive pad 6.

At least one of the circuit traces 71 of the first mounting substrate 7 is electrically connected to a corresponding one of the circuit traces 81 of the second mounting substrate 8 via a conductive pad 6.

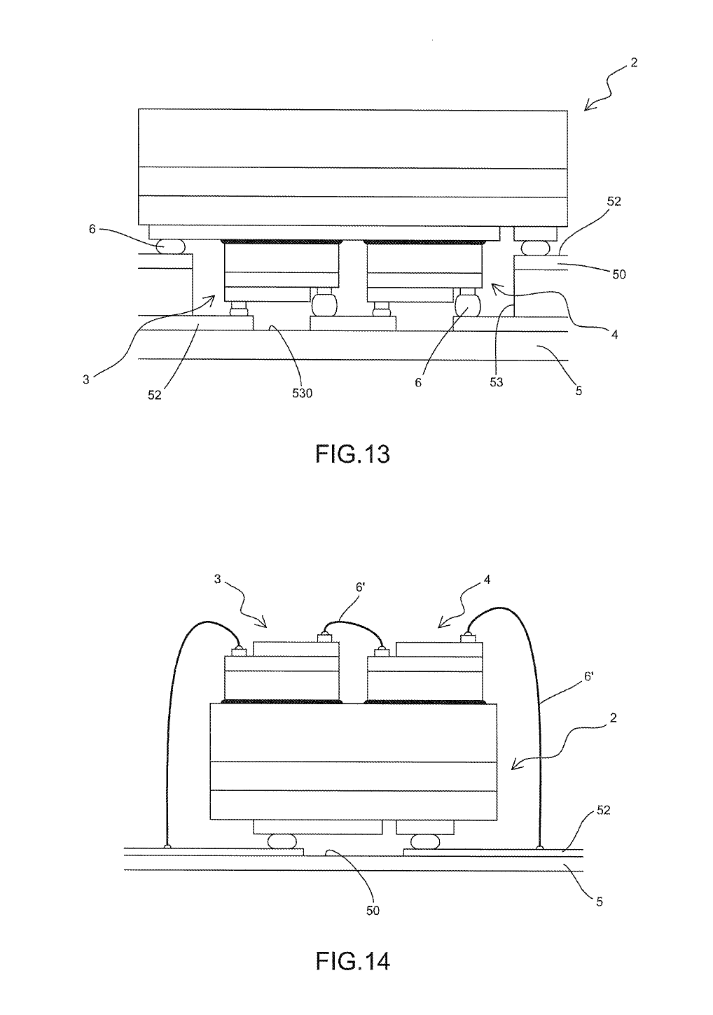

FIG. 13 is a schematic view of the LED device according to the eighth preferred embodiment of the invention.

As shown in FIG. 13, the LED device according to this embodiment comprises a first LED chip 2, a second LED chip 3, a third LED chip 4 and a mounting substrate 5.

In this embodiment, the substrate 5 comprises a mounting surface 50, a recess portion 53, and a plurality of circuit traces 52 overlaid on the mounting surface 50 and on a bottom surface 530 of the recess portion 53.

The first LED chip 2 is mounted on the substrate 5 and comprises a sapphire substrate 20, an N-type semiconductor layer 21 disposed on the sapphire substrate 20, a P-type semiconductor layer 22 disposed on the N-type semiconductor layer 21, and N-type and P-type electrodes 210, 220 electrically connected to the N-type semiconductor layer 21 and the P-type semiconductor layer 22, respectively, and adapted for electrical connection to external circuitry (not shown). The first LED chip 2 is flip-chip mounted on the mounting surface 50 of the substrate 5 via conductive pads 6.

The second LED chip 3 may have a configuration identical to the first LED chip 2 and is flip-chip mounted on the bottom surface 530 of the recess portion 53 of the substrate 5 via conductive pads 6.

The third LED chip 4 may have a configuration identical to the second LED chip 3 and is flip-chip mounted on the bottom surface 530 of the recess portion 53 of the substrate 5 via conductive pads 6, so that the P-type electrode 420 of the third LED chip 4 is electrically connected to the N-type electrode 310 of the second LED chip 3.

FIG. 14 is a schematic view of the LED device according to the ninth preferred embodiment of the invention.

As shown in FIG. 14, the LED device according to this embodiment comprises a first LED chip 2, a second LED chip 3, a third LED chip 4 and a mounting substrate 5.

The mounting substrate 5 comprises a mounting surface 50, and a plurality of predetermined circuit traces 52 overlaid on the mounting surface 50.

The first LED chip 2 has a configuration identical to the first LED chip 2 disclosed in the eighth preferred embodiment and is flip-chip mounted on the mounting surface 50 of the substrate 5 via conductive pads 6.

The second LED chip 3 has a configuration identical to the second LED chip 3 disclosed in the eighth preferred embodiment and is mounted on a surface of the substrate 20 of the first LED chip 2 opposite to the surface on which the semiconductor layers 21, 22 are disposed.

The third LED chip 4 has a configuration identical to the third LED chip 4 disclosed in the eighth preferred embodiment and is mounted alongside the second LED chip 3 on a surface of the substrate 20 of the first LED chip 2 opposite to the surface on which the semiconductor layers 21, 22 are disposed.

The N-type electrode 310 of the second LED chip 3 and the P-type electrode 420 of the third LED chip 4 are electrically connected to the corresponding circuit traces 52 via separate conductive wires 6′, while the P-type electrode 320 of the second LED chip 3 is electrically connected to the N-type electrode 410 of the third LED chip 4 via a conductive wire 6′.

In conclusion, the light-emitting diode devices disclosed herein can surely achieve the intended objects and effects of the invention by virtue of the structural arrangements and operating steps described above.

While the invention has been described with reference to the preferred embodiments above, it should be recognized that the preferred embodiments are given for the purpose of illustration only and are not intended to limit the scope of the present invention and that various modifications and changes, which will be apparent to those skilled in the relevant art, may be made without departing from the spirit of the invention and the scope thereof as defined in the appended claims.

What is claimed is:

1. A light-emitting diode device, comprising:
a light-emitting diode (LED) chip comprising a sapphire substrate, a first-type semiconductor layer disposed on the substrate, a second-type semiconductor layer disposed on the first-type semiconductor layer, a first via hole passing through the sapphire substrate and the first-type semiconductor layer, a second via hole passing through the sapphire substrate, and an insulation layer coated on an inner wall of the first via hole;
a transparent conductive layer made of electrically conductive material and formed on the second-type semiconductor layer;
a cover layer formed on the transparent conductive layer;
electrical conductors, each disposed within one of the via holes, wherein the electrical conductor in the first via hole is electrically connected to the second-type semiconductor layer and the electrical conductor in the second via hole is electrically connected to the first-type semiconductor layer; and
two linkers adapted for connection to external circuitry, formed on a surface of the sapphire substrate opposite to the surface on which the first-type and second-type semiconductor layers are disposed.

2. The light-emitting diode device according to claim 1, wherein each of the linkers is electrically connected to a corresponding one of the electrical conductors and comprises a first conductive layer disposed on the sapphire substrate and electrically connected to the electrical conductor corresponding thereto, a reflective conductive layer formed on the first conductive layer, a second conductive layer formed on the reflective layer, and a third conductive layer formed on the second conductive layer.

3. The light-emitting diode device according to claim 2, wherein the first conductive layer is made of indium tin oxide (ITO), the reflective layer is made of any suitable conductive material, the second conductive layer is a nickel/gold layer, and the third conductive layer is configured in the form of a bump.

4. The light-emitting diode device according to claim 1, wherein the transparent conductive layer is made of conductive ITO.

5. The light-emitting diode device according to claim 1, further comprising a laminated transparent light guide layer formed atop the cover layer and adapted to direct light towards a single direction, so that the light emitted the LED device is concentrated to increase brightness.

6. The light-emitting diode device according to claim 5, wherein the laminated transparent light guide layer includes a plurality of sub-layers having refractive indexes of 2.22.3/2.3˜2.4/2.2˜2.3/2.3˜2.4, respectively, and wherein the laminated transparent light guide layer has an overall refractive index close to the refractive indexes 2.4˜2.5 of gallium nitride (GaN) or gallium arsenide (GaAs) and is adapted for directing blue light towards a single direction and avoiding multiple reflection of light.

7. The light-emitting diode device according to claim 1, wherein the first-type and second-type semiconductor layers, and the surface of the first-type and second-type sapphire substrate opposite to the surface on which the semiconductor layers are disposed, have edges configured into diamond light-guide edges, thereby increasing light emission by more than 20%.

8. The light-emitting diode device according to claim 1, wherein the first via hole further passes through the second-type semiconductor layer, so that the electrical conductor in the first via hole is electrically connected to the transparent conductive layer disposed on the second-type semiconductor layer.

9. A method for producing a light-emitting diode device, comprising the steps of:
providing a light-emitting diode (LED) wafer, the LED wafer comprising a plurality of adjacent LED chips, each being separate from an adjacent one of the LED chips by a dicing line and comprising a sapphire substrate, a first-type semiconductor layer disposed on the substrate, and a second-type semiconductor layer disposed on the first-type semiconductor layer;
forming a first via hole passing through the sapphire substrate and the first-type semiconductor layer, and a second via hole passing through the sapphire substrate;
coating an insulation layer on an inner wall of the first via hole;
forming an electrical conductor within the first and second via holes, respectively, so that the electrical conductor in the via first hole is electrically connected to the second-type semiconductor layer and the electrical conductor in the second via hole is electrically connected to the first-type semiconductor layer;
forming a transparent conductive layer on the second-type semiconductor layer;
forming a cover layer on the transparent conductive layer; and
forming a laminated light guide layer on the cover layer.

10. A light-emitting diode device, comprising:
a first light-emitting diode (LED) chip comprising a sapphire substrate, a first-type semiconductor layer disposed on the substrate, a second-type semiconductor layer disposed on the first-type semiconductor layer, a first via hole passing through the sapphire substrate and the first-type semiconductor layer, a second via hole passing through the sapphire substrate, an insulation layer coated on an inner wall of the first via hole, a transparent conductive layer made of electrically conductive material and formed on the second-type semiconductor layer, a cover layer formed on the transparent conductive layer, three conductive islands formed on the cover layer and electrically insulated from one another, a communication hole connecting the conductive layer to a corresponding one of the conductive islands, a through hole connecting the first-type semiconductor layer to a corresponding one of the conductive island, and an insulation layer coated on inner walls of the communication hole and the through hole, wherein the communication hole and the through hole are filled with conductive material, so that one of the three conductive island is electrically connected to the conductive layer and another one of the three conductive island is electrically connected to the first-type semiconductor layer of the first LED chip;
a second LED chip flip-chip mounted on the cover layer of the first LED chip, so that the second-type semiconductor layer of the second LED chip is electrically connected to the conductive island to which the conductive layer of the first LED chip is electrically connected, and that the first-type semiconductor layer of the second LED chip is electrically connected to one of the three conductive islands which is not electrically connected to either the conductive layer of the first LED chip or the first-type semiconductor layer of the first LED chip; and
a third LED chip flip-chip mounted on the cover layer of the first LED chip, so that the second-type semiconductor layer of the third LED chip is electrically connected to the conductive island to which the first-type semiconductor layer of the second LED chip is electrically connected, and that the first-type semiconductor layer of the third LED chip is electrically connected to the conductive island to which the first-type semiconductor layer of the first LED chip is electrically connected;
wherein the LED chips are each adapted to emit a different color of light upon being energized, so that the LED device is capable of providing a desired color of light upon combining the different colors of light emitted from the LED chips.

11. A light-emitting diode device, comprising:
a substrate, which is a transparent substrate and has a first mounting surface and a second mounting surface opposite to the first mounting surface, wherein a plurality of transparent conductive traces are formed on the first mounting surface and some of the conductive traces extend from the first mounting surface to the second mounting surface;
a first LED chip mounted on the substrate, comprising a sapphire substrate disposed on the first mounting surface of the substrate, a first-type semiconductor layer disposed on the sapphire substrate, a second-type semiconductor layer disposed on the first-type semiconductor layer, and first-type and second-type electrodes electrically connected to the first-type semiconductor layer and the second-type semiconductor layer, respectively, and adapted for electrical connection to external circuitry;
a second LED chip having a configuration identical to the first LED chip and flip-chip mounted on the first mounting surface of the substrate, so that the second-type electrode of the second LED chip is electrically connected to one of the conductive traces extending from the first mounting surface to the second mounting surface, and that the first-type electrode of the second LED chip is electrically connected to one of the conductive traces which does not extend to the second mounting surface;
a third LED chip having a configuration identical to the first LED chip and flip-chip mounted on the first mounting surface of the substrate, so that the second-type electrode of the third LED chip is electrically connected to the conductive trace to which the first-type electrode of the second LED chip is electrically connected, and that the first-type electrode of the third LED chip is electrically connected to another one of the conductive traces extending from the first mounting surface to the second mounting surface; and
a plurality of conductive pads for electrical connection to external circuitry, formed on the first-type and second-type electrodes of the first LED chip and on the extension portions of the conductive traces which extend on the second mounting surface, respectively.

12. A light-emitting diode device, comprising:
a first LED chip comprising a sapphire substrate, a first-type semiconductor layer disposed on the sapphire substrate, a second-type semiconductor layer disposed on the first-type semiconductor layer, and first-type and second-type electrodes electrically connected to the first-type semiconductor layer and the second-type semiconductor layer, respectively, and adapted for electrical connection to external circuitry, wherein the first LED chip is formed with two through holes passing through the substrate and the semiconductor layers, and the through holes are coated on their inner walls with an insulation layer, and wherein a plurality of transparent conductive traces are formed on a surface of the substrate opposite to the surface on which the semiconductor layers are disposed, and some of the conductive traces extend through the through holes and protrude out from the first LED chip;
a second LED chip having a configuration identical to the first LED chip and flip-chip mounted on the surface of the substrate of the first LED chip on which the conductive traces are mounted, so that the second-type electrode of the second LED chip is electrically connected to one of the conductive traces extending through the through holes, and that the first-type electrode of the second LED chip is electrically connected to one of the conductive trace which does not extend into anyone of the through holes;
a third LED chip having a configuration identical to the first LED chip and flip-chip mounted on the surface of the substrate of the first LED chip on which the conductive traces are mounted, so that the second-type electrode of the third LED chip is electrically connected to the conductive traces to which the first-type electrode of the second LED chip is electrically connected, and that the first-type electrode of the third LED chip is electrically connected to the other one of the conductive traces extending through the through holes; and
a plurality of conductive pads for electrical connection to external circuitry, formed on the first-type and second-type electrodes of the first LED chip and on the protruded portions of the conductive traces which extend through the through holes and protrude out from the first LED chip, respectively.

13. A light-emitting diode device, comprising:
a first LED chip comprising a sapphire substrate, a first-type semiconductor layer disposed on the sapphire substrate, a second-type semiconductor layer disposed on the first-type semiconductor layer, first-type and second-type electrodes adapted for electrical connection to external circuitry, and two through holes pas sing through the sapphire substrate, the first-type semiconductor layer and the second-type semiconductor layer, wherein the through holes are coated on their inner walls with an insulation layer;
a second LED chip comprising a sapphire substrate disposed on a surface of the sapphire substrate of the first LED chip opposite to the surface on which the first-type semiconductor layer of the first LED chip is disposed, a first-type semiconductor layer disposed on the sapphire substrate, and a second-type semiconductor layer disposed on the first-type semiconductor layer, wherein the first-type semiconductor layer and the second-type semiconductor layer are formed with a first-type electrode and a second-type electrode, respectively;
a third LED chip mounted alongside the second LED chip on the surface of the sapphire substrate of the first LED chip opposite to the surface on which the first-type semiconductor layer of the first LED chip is disposed, the third LED chip comprising a sapphire substrate disposed on the substrate of the first LED chip, a first-type semiconductor layer disposed on the sapphire substrate, and a second-type semiconductor layer disposed on the first-type semiconductor layer, wherein the first-type semiconductor layer and the second-type semiconductor layer are formed with a first-type electrode and a second-type electrode, respectively;
a plurality of conductors, wherein one of the conductors extends from the first-type electrode of the second LED chip through one of the through holes and further protrudes out from the first LED chip, another one of the conductors extends from the second-type electrode of the third LED chip through the other one of the through holes and further protrudes out from the first LED chip, and a still another one of the conductors extends from the second-type electrode of the second LED chip to the first-type electrode of the third LED chip; and
a plurality of conductive pads for electrical connection to external circuitry, formed on the first-type and second-type electrodes of the first LED chip and on the protruded portions of the conductors which extend through the through holes and protrude out from the first LED chip, respectively.

14. A light-emitting diode device, comprising:
a first mounting substrate including a first surface and a plurality of predetermined circuit traces overlaid on the first surface;
a first LED chip comprising a sapphire substrate, a first-type semiconductor layer disposed on the sapphire substrate, a second-type semiconductor layer disposed on the first-type semiconductor layer, and first-type and second-type electrodes adapted for electrical connection to external circuitry, wherein each of the electrodes is formed with a conductive pad and the first LED chip is flip-chip mounted on the first mounting substrate by electrically connecting the conductive pads to the corresponding circuit traces overlaid on the first mounting substrate;
a second LED chip comprising a sapphire substrate disposed on a surface of the sapphire substrate of the first LED chip opposite to the surface on which the first-type semiconductor layer of the first LED chip is disposed, a first-type semiconductor layer disposed on the sapphire substrate, and a second-type semiconductor layer disposed on the first-type semiconductor layer, wherein the first-type semiconductor layer and the second-type semiconductor layer are formed with a first-type electrode and a second-type electrode, respectively;
a third LED chip mounted alongside the second LED chip on the surface of the sapphire substrate of the first LED chip opposite to the surface on which the first-type semiconductor layer of the first LED chip is disposed, the third LED chip comprising a sapphire substrate disposed on the substrate of the first LED chip, a first-type semiconductor layer disposed on the sapphire substrate, and a second-type semiconductor layer disposed on the first-type semiconductor layer, wherein the first-type semiconductor layer and the second-type semiconductor layer are formed with a first-type electrode and a second-type electrode, respectively; and
a second mounting substrate, comprising a first surface and a plurality of predetermined circuit traces overlaid on the first surface, the first surface of the second mounting substrate being oppositely mounted with respect to the first surface of the first mounting substrate, so that the first-type electrode of the second LED chip is electrically connected to one of the predetermined circuit traces of the second mounting substrate via a conductive pad, the second-type electrode of the second LED chip and the first-type electrode of the third LED chip is electrically connected to one of the predetermined circuit traces of the second mounting substrate via conductive pads, respectively, and the second-type electrode of the third LED chip is electrically connected to one of the predetermined circuit traces of the second mounting substrate via a conductive pad;
wherein at least one of the circuit traces of the first mounting substrate is electrically connected to a corresponding one of the circuit traces of the second mounting substrate via a conductive pad.

15. A light-emitting diode device, comprising:
a mounting substrate comprising a mounting surface, a recess portion, and a plurality of circuit traces overlaid on the mounting surface and on a bottom surface of the recess portion;
a first LED chip mounted on the substrate, comprising a sapphire substrate, a first-type semiconductor layer disposed on the sapphire substrate, a second-type semiconductor layer disposed on the first-type semiconductor layer, and first-type and second-type electrodes electrically connected to the first-type semiconductor layer and the second-type semiconductor layer, respectively, and adapted for electrical connection to external circuitry, wherein the first LED chip is flip-chip mounted on the mounting surface of the substrate via conductive pads;
a second LED chip flip-chip mounted on the bottom surface of the recess portion of the substrate via conductive pads; and
a third LED chip flip-chip mounted on the bottom surface of the recess portion of the substrate via conductive pads, so that the second-type electrode of the third LED chip is electrically connected to the first-type electrode of the second LED chip.

16. A light-emitting diode device, comprising:
a mounting substrate comprising a mounting surface and a plurality of predetermined circuit traces overlaid on the mounting surface;
a first LED chip flip-chip mounted on the mounting surface of the substrate via conductive pads;
a second LED chip mounted on a surface of the substrate of the first LED chip opposite to the surface on which semiconductor layers are disposed;
a third LED chip mounted alongside the second LED chip on a surface of the substrate of the first LED chip opposite to the surface on which the semiconductor layers are disposed; and
wherein the first-type electrode of the second LED chip and the second-type electrode of the third LED chip are electrically connected to the circuit traces corresponding thereto via separate conductive wires, and the second-type electrode of the second LED chip is electrically connected to the first-type electrode of the third LED chip via a conductive wire.
